(19) United States
(12) Patent Application Publication
(10) Pub. No.: US 2019/0033404 A1
(43) Pub. Date: Jan. 31, 2019

(54) ARTICULATED GUIDE TUBE

(71) Applicant: KONINKLIJKE PHILIPS N.V., EINDHOVEN (NL)

(72) Inventor: JAMES HOWARD KRALICK, LATHAM, NY (US)

(21) Appl. No.: 16/083,559

(22) PCT Filed: Mar. 3, 2017
(86) PCT No.: PCT/IB2017/051237

§ 371 Date: Sep. 10, 2018

Related U.S. Application Data
(60) Provisional application No. 62/308,485, filed on Mar. 15, 2016.

(51) Int. Cl. G01R 33/3815; G01R 33/38; H01F 6/06

(52) U.S. Cl. CPC G01R 33/3815; H01F 6/065; G01R 33/3804

(57) ABSTRACT

A magnetic resonance (MR) system includes: a cryogenic vessel disposed around superconducting coils. The cryogenic vessel is configured to receive coolant. The MR system also includes a guide tube connected to the cryogenic vessel, and configured to provide the coolant, and an electrical lead. The guide tube includes a joint about which a first portion of the guide tube pivots relative to a second portion.

### BACKGROUND

Magnetic Resonance Imaging (MM) technology is commonly used today in medical institutions worldwide, and has led to significant and unique benefits in the practice of medicine. While MRI has been developed as a well-established diagnostic tool for imaging structure and anatomy, it has also been developed for imaging functional activities and other biophysical and biochemical characteristics or processes (e.g., blood flow, metabolites/metabolism, diffusion), some of these magnetic resonance (MR) imaging techniques being known as functional MRI, spectroscopic MRI or Magnetic Resonance Spectroscopic Imaging (MRSI), diffusion weighted imaging (DWI), and diffusion tensor imaging (DTI). These magnetic resonance imaging techniques have broad clinical and research applications in addition to their medical diagnostic value for identifying and assessing pathology and determining the state of health of the tissue examined.

During a typical MM examination, a patient's body (or a sample object) is placed within the examination region and is supported by a patient support in an MM scanner where a substantially constant and uniform primary (main) magnetic field is provided by a primary (main) magnet. The magnetic field aligns the nuclear magnetization of precessing atoms such as hydrogen (protons) in the body. A gradient coil assembly within the magnet creates a small variation of the magnetic field in a given location, thus providing resonance frequency encoding in the imaging region. A radio frequency (RF) coil is selectively driven under computer control according to a pulse sequence to generate in the patient a temporary oscillating transverse magnetization signal that is detected by the RF coil and that, by computer processing, may be mapped to spatially localized regions of the patient, thus providing an image of the region-of-interest under examination.

In a common MRI configuration, the static main magnetic field is typically produced by a solenoid magnet apparatus, and a patient platform is disposed in the cylindrical space bounded by the solenoid windings (i.e. the main magnet bore), which are maintained at low temperature.

Typically, the cryostat comprises a vessel into which a coolant (e.g., liquid helium) is introduced. This vessel, sometimes referred to the 4k vessel, is disposed around superconducting windings.

The coolant is introduced via another tube, typically called a guide tube, which includes a tube for introducing the coolant, and at least one other tube used to introduce electrical leads to ramp up and ramp down the magnet.

Often, during operation, ice forms on and around components within the 4k vessel. This ice must be removed to ensure proper function of the magnet. Typically, deicing requires introducing a warming gas (e.g., gaseous helium) to regions in which ice has formed. Unfortunately, the comparatively low ceiling height in the region of the guide tube prohibits the removal of the guide tube, making the introduction of warming gas quite difficult.

What is needed, therefore, is an apparatus that overcomes at least the shortcomings described above

### SUMMARY

In accordance with a representative embodiment, a magnetic resonance (MR) system, comprises: a cryogenic vessel disposed around superconducting coils, the cryogenic vessel configured to receive coolant; and a guide tube connected to the cryogenic vessel, and configured to provide the coolant, and an electrical lead, the guide tube comprising a joint about which a first portion of the guide tube pivots relative to a second portion.

In accordance with another representative embodiment, a guide tube, comprises: a first tube, a second tube, and a third tube, each of the tubes comprising respective first and second sections, each configured to rotate about the joint. The first, second and third tubes have a first height in a first position, and a second height in a second position, the second height being less than the first height.

In accordance with another representative embodiment, a method of removing ice from a portion of an MR system is disclosed. The method comprises: rotating a guide tube in a first direction at a joint about which a first portion of the guide tube pivots relative to a second portion; removing the guide tube from the MR system; applying a gas to the portion of the MR system to melt the ice; returning the guide tube to the MR system; and rotating the first portion of the guide tube a second direction at joint.

### BRIEF DESCRIPTION OF THE DRAWINGS

The representative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified schematic block diagram of an MR system in accordance with a representative embodiment.

FIG. 2A is a perspective view of a portion of an MR magnet in accordance with a representative embodiment.

FIG. 2B is a perspective view of an articulated guide tube in accordance with a representative embodiment.

FIG. 2C is a perspective view of a guide tube prepared for removal from an MR magnet in accordance with a representative embodiment.

FIG. 3 is a flow chart of a method in accordance with a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ comprises both singular and plural referents, unless the context clearly dictates otherwise. Thus, for example, ‘a device’ includes one device and plural devices.

As used herein, the statement that two or more parts or components are “connected” shall mean that the parts are joined or operate together either directly or indirectly, i.e., through one or more intermediate parts or components, so long as a link occurs.

Directional terms/phrases and relative terms/phrases may be used to describe the various elements' relationships to one another, as illustrated in the accompanying drawings. These terms/phrases are intended to encompass different orientations of the device and/or elements in addition to the orientation depicted in the drawings.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

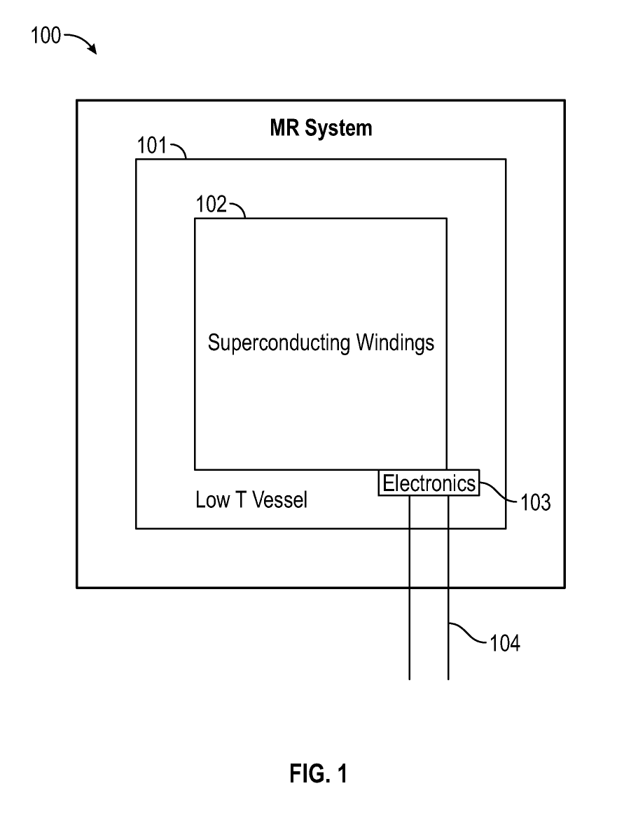

FIG. 1 is a simplified schematic block diagram of an MR system 100 in accordance with a representative embodiment. The MR system 100 in combination with known components, many of which are not depicted in FIG. 1, may be used to provide MR images, which are used, for example, in medical diagnostics.

The MR system 100 comprises a low temperature (LT) vessel 101 (sometimes referred to herein as a cryogenic vessel, or a 4 K vessel). The LT vessel 101 is generally filled with a material at low temperature, such as liquid helium, to maintain the temperature of the LT vessel 101 close to absolute zero (0 Kelvin/−273° C.). Superconducting windings 102 are disposed in the LT vessel 101. The superconducting windings 102 generate the main magnetostatic field, and typically comprise a low temperature superconductor (LTS) material. The superconducting windings 102 are super-cooled with liquid helium in order to reduce resistance, and, therefore, to minimize the amount of heat generated and the amount of power necessary to create and maintain the main field. Illustratively, the superconducting windings are made of a niobium-titanium (NbTi) and/or Nb₃Sn material which is cooled with a cryostat to a temperature of 4.2 K.

Electronics 103 are also disposed in the LT vessel 101. The electronics 103 illustratively comprise a terminal circuit board (i.e., a TB1 board). Leads (not shown) are connected from outside the LT vessel 101 to the electronics 103 when supplying electrical power to the superconducting windings to generate the full magnetic field strength (also known as ramping the superconducting magnet), and when terminating the electrical power to terminate the generation of the magnetic field (unramping) when, for example, servicing the MR system 100.

A guide tube 104 provides a connection between the ambient environment and the LT vessel 101. Notably, the guide tube 104 provides the only physical connection or conduit to the interior of the LT vessel 101. As described more fully below, the guide tube 104 comprises individual tubes that are used to provide the coolant (liquid helium) to the LT vessel, and ramping leads, and unramping leads to the electronics 103.

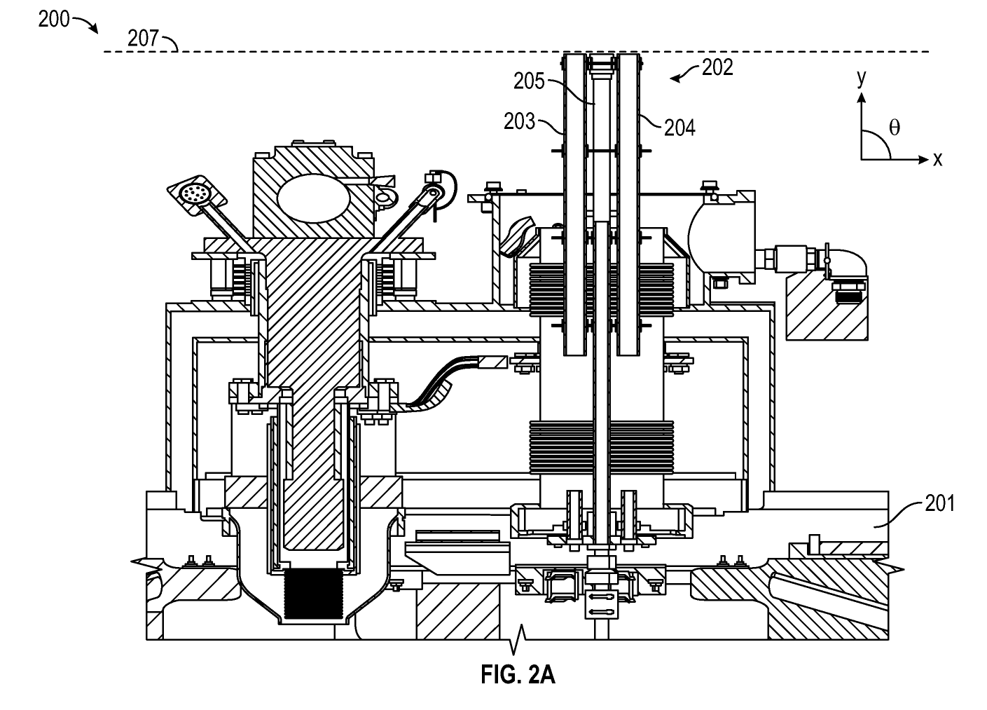

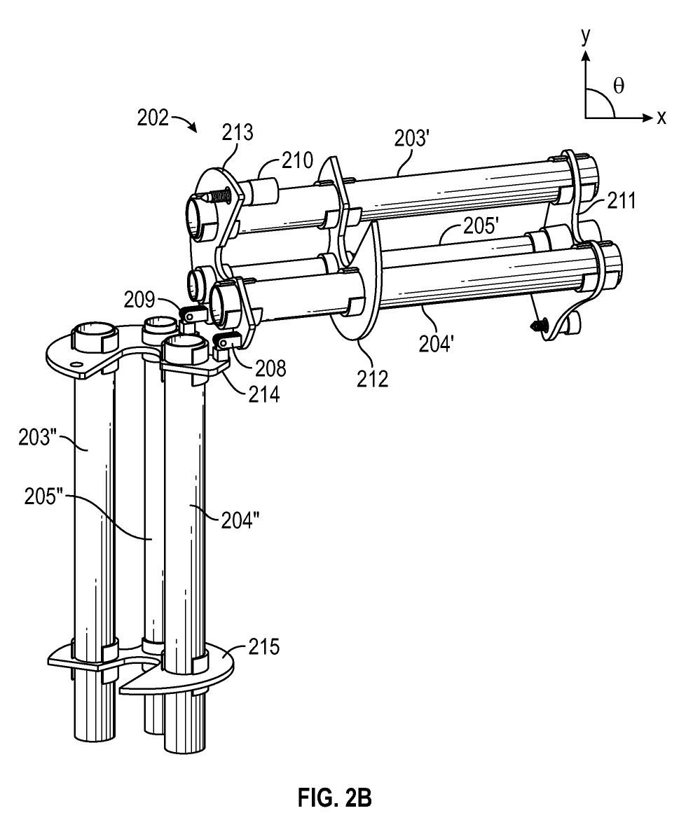

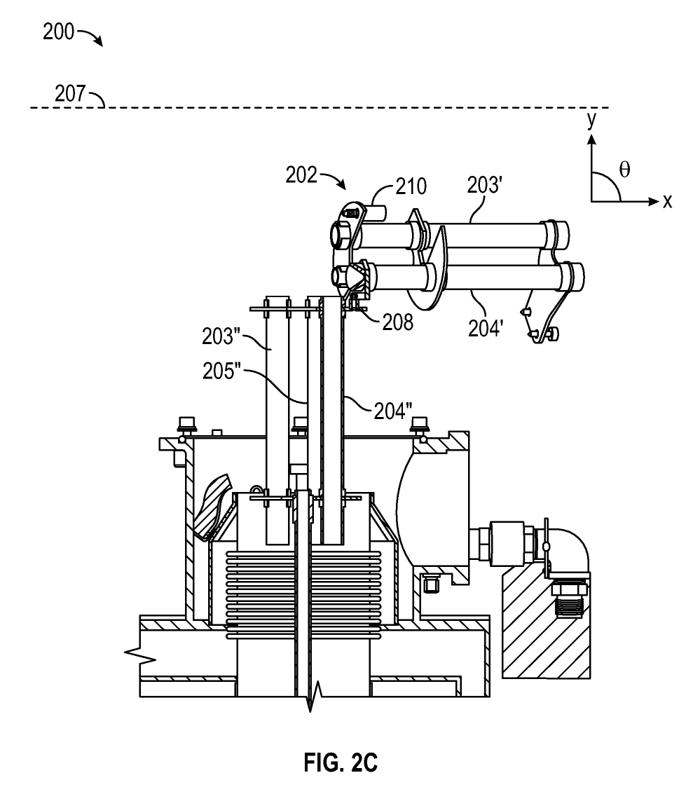

FIG. 2A is a perspective view of a portion of an MR magnet 200 in accordance with a representative embodiment. Many aspects of the description of the MR magnet 200 are common to those of the MR system 100 described in connection with FIG. 1. Often, details of these common aspects are not repeated in the description of the representative embodiment described in connection with FIG. 2A.

The MR magnet 200 comprises an LT vessel 201. As noted above, superconducting windings (not shown in FIG. 2A), are disposed in the LT vessel 201.

The MR magnet 200 also comprises a guide tube 202. The guide tube 202 illustratively comprises a first tube 203, a second tube 204, and a third tube 205. The number of tubes is merely illustrative, and more or fewer tubes could be used without departing from the spirit of the present teachings.

The first, second, and third tubes 203˜205 are substantially hollow, and are made of a material suitable for low temperature applications. By way of example, the first, second, and third tubes 203˜205 comprise an epoxy laminate material commonly referred to as G10 glass. It is noted that this is merely illustrative, and that other materials within the purview of one of ordinary skill in the art are contemplated for use in the first, second, and third tubes 203˜205.

As noted above, the first, second, and third tubes 203˜205 are used to provide ramping and unramping leads to electronics (not shown in FIG. 2A), and coolant to the LT vessel 201. Illustratively, the first and second tubes 203, 204 may be used for providing the ramping and unramping leads, and third tube 205 may be used to provide the coolant.

The MR magnet 200 comprises a ceiling 207, which is required to provide a minimum ceiling height. In known MR systems, deicing is problematic because removal of the guide tube is required to properly deice the electronics, for example. Known guide tubes cannot be raised vertically (y-direction in the coordinate system shown) sufficiently to remove the guide tube.

By contrast, the guide tube 202 is articulated, and is readily removed from the MR magnet 200 to allow introduction of coolant gas via a nozzle to electronics for deicing. As will be described more fully below, each of the first, second, and third tubes 203˜205 comprise first and second portions, and the first portions are initially aligned parallel to the x-axis in the coordinate system depicted in FIG. 2A, and are adapted to rotate over at least a portion of angle Θ toward the y-axis in the depicted coordinate system. This rotation reduces the height of the guide tube 202 so it can be removed from the MR magnet 200.

FIG. 2B is a perspective view of guide tube 202 in accordance with a representative embodiment. Many aspects of the description of the guide tube 202 are common to those described in connection with FIG. 2A. Often, details of these common aspects are not repeated in the description of the representative embodiment described in connection with FIG. 2B.

The guide tube 202 comprises first portions 203′, 204′ and 205′, and second portions 203″, 204″ and 205.″ Collectively, the first portions 203′, 204′ and 205′ are referred to as first portion 202′ of guide tube 202; and second portions 203″, 204″ and 205″ are referred to as second portion 202″ of guide tube 202.

As shown, the first portions 203′, 204′ and 205′ are held in position with first, second and third brackets 211, 212, 213; and the second portions 203″, 204″ and 205″ are held in position by third and fourth brackets 214, and 215. The first˜fifth brackets 211˜215 may be made of metal, or plastic, or other suitable material. Collectively, the first portions 203′, 204′ and 205′ are referred to as first portion 202′ of guide tube 202; and second portions 203″, 204″ and 205″ are referred to as second portion 202″ of guide tube 202.

As described more fully herein, first portions 203′, 204′ and 205′, and second portions 203″, 204″ and 205 rotate about first and second hinges 208, 209, which are disposed between third and fourth brackets 213, 214.

The guide tube 202 is depicted in a rotated position, with respective first portions 203′, 204′ and 205′ being rotated relative to respective second portions 203″, 204″ and 205″ so that the first portions 203′, 204′ and 205′ are substantially orthogonal to respective second portions 203″, 204″ and 205″.

As can be appreciated, when the 203′, 204′ and 205′ are not rotated relative respective second portions 203″, 204″ and 205″. As such, each of first portions 203′, 204′ and 205′ is mated to respective second portions 203″, 204″ and 205″, are locked in position by screw 210, and form the first, second and third tubes 203, 204 and 205. In this position, the first, second and third tubes 203, 204 and 205, which comprise the guide tube 202 have a first height (y-direction in the coordinate system depicted).

By contrast, when the first portions 203′, 204′ and 205′ are rotated about first and second hinges 208, 209 as in FIG. 2B, relative respective second portions 203″, 204″ and 205″, each of first portions 203′, 204′ and 205′ are not mated to respective second portions 203″, 204″ and 205″. In this position, the height of the first and second portions of the guide tube 202 have a second height (y-direction in the coordinate system depicted), which is less than the first height. As can be appreciated, when the first portions 203′, 204′ and 205′ are rotated by Θ=90° (as in FIG. 2B) relative respective second portions 203″, 204″ and 205″, the difference between the second height and the first height is the greatest. Of course, the degree of the rotation is mandated by the degree of height reduction of the components of the guide tube 202, and rotations less than Θ<90° are contemplated.

FIG. 2C is a perspective view of a guide tube prepared for removal from MR magnet 200 in accordance with a representative embodiment. Many aspects of the description of the MR magnet 200 are common to those of the MR system 100 described in connection with FIG. 1. Similarly, many aspects of the description of the guide tube 202 are common to those described in connection with FIGS. 2A, 2B. Often, details of these common aspects are not repeated in the description of the representative embodiment described in connection with FIG. 2C.

As noted above, MR magnet 200 comprises a ceiling 207, which is required to provide a minimum ceiling height. As shown, guide tube 202 is articulated, and is readily removed from the MR magnet 200 to allow introduction of coolant gas via a nozzle to electronics for deicing. Specifically, and as described in connection with FIG. 2B, the first portions 203′, 205′ (not visible in FIG. 2C), and 205′ are rotated about first and second hinges 208 and 209 (not visible in FIG. 2C), and are substantially orthogonal to second portions 203″, 204″, 205″ in the depicted embodiment. In this configuration, the guide tube 202 can be raised (y-direction in the coordinate system of FIG. 2C) sufficiently for removal, and uninhibited by the ceiling 207. Stated somewhat differently, the rotation over at least a portion of angle Θ toward the y-axis in the depicted coordinate system reduces the height of the guide tube 202 so it can be removed from the MR magnet 200.

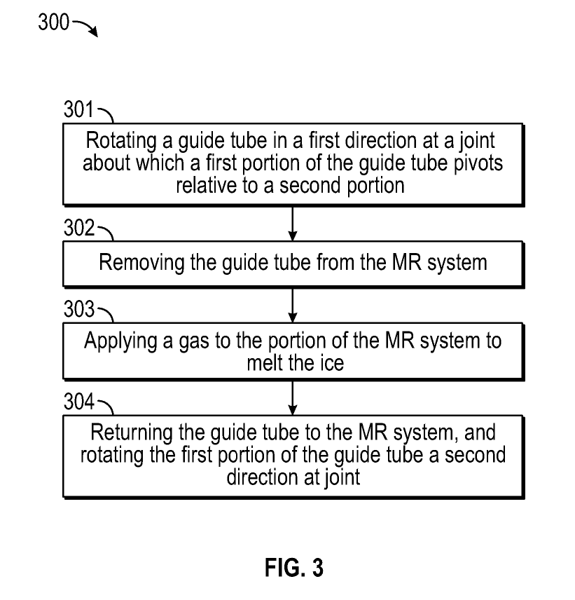

Generally, the method of deicing comprises removing the guide tube 202, deicing the areas of the MR magnet 200 where ice has formed (e.g., around electronics 103), and re-installing the guide tube. An illustrative method is presently described in connection with FIG. 3.

FIG. 3 is a flow-chart of a method 300 of removing ice from a portion of an MR system. Many aspects of the description of the method 300 are common to those described in connection with FIGS. 1˜2C. Often, details of these common aspects are not repeated in the description of the representative embodiment described in connection with FIG. 3.

At 301, the method comprises rotating a guide tube in a first direction at a joint about which a first portion of the guide tube pivots relative to a second portion.

At 302, the method comprises removing the guide tube 202 from the MR magnet 200.

At 303, after removal of the guide tube 202, the method comprises applying a gas to the portion of the MR system to melt the ice. As noted above, the gas may be helium, applied using a wand or similar device to direct the gas to the ice.

At step 304, the method comprises returning the guide tube to the MR system; and rotating the first portion of the guide tube a second direction at joint.

In view of this disclosure it is noted that the various components, materials and parameters of the MR system, and the guide tube, and method are included by way of example only and not in any limiting sense. In view of this disclosure, those skilled in the art can implement the present teachings in determining their own applications and needed materials and equipment to implement these applications, while remaining within the scope of the appended claims.

1. A magnetic resonance (MR) system, comprising:
a cryogenic vessel disposed around superconducting coils, the cryogenic vessel configured to receive coolant; and
a guide tube connected to the cryogenic vessel, and configured to provide the coolant, and an electrical lead, the guide tube comprising at least one tube and a joint about which a first portion of the at least one tube of the guide tube pivots relative to a second portion.

2. The MR system of claim 1, wherein the at least one tube of the guide tube comprises:
a first tube, a second tube, and a third tube, each of the tubes comprising respective first and second sections, each configured to rotate about the joint.

3. The MR system of claim 2, wherein the first, second and third tubes have a first height in a first position, and a second height in a second position, the second height being less than the first height.

4. The MR system of claim 3, wherein, in the second position, the first portions of the respective first, second, and third tubes are disposed at an angle of approximately 90° relative to the second portions of the respective first, second, and third tubes.

5. The MR system of claim 2, wherein the first, second, and third tubes each have proximal and distal ends, wherein the distal ends are disposed in the cryogenic vessel.

6. The MR system of claim 5, wherein the electrical lead comprises a ramping lead and an unramping lead, and the first and second tubes are configured to receive the ramping lead and the unramping lead respectively.

7. The MR system of claim 6, wherein the third tube is configured to introduce the coolant to the cryogenic vessel.

8. The MR system of claim 2, wherein each of the first, second, and third tubes comprises an epoxy laminate material.

9. A guide tube, comprising:
a joint;
a first tube, a second tube, and a third tube, each of the tubes comprising respective first and second sections, each configured to rotate about the joint, wherein the first, second and third tubes have a first height in a first position, and a second height in a second position, the second height being less than the first height.

10. The guide tube of claim 9, wherein, in the second position, the first portions of the respective first, second, and third tubes are disposed at an angle of approximately 90° relative to the second portions of the respective first, second, and third tubes.

11. The guide tube of claim 10, wherein the first, second, and third tubes each have proximal and distal ends, wherein the distal ends are disposed in a cryogenic vessel.

12. The guide tube of claim 11, wherein first and second tubes are configured to receive a ramp lead and an unramp lead, respectively.

13. The guide tube of claim 11, wherein the third tube is configured to introduce coolant to a cryogenic vessel.

14. The guide tube of claim 9, wherein each of the first, second, and third tubes comprises an epoxy laminate material.

15. (canceled)
